(19) United States
(12) Patent Application Publication
(10) Pub. No.: US 2026/0255628 A1
(43) Pub. Date: Aug. 27, 2026

(54) SEMICONDUCTOR DEVICE AND METHOD OF MANUFACTURING THE SAME

(71) Applicant: Powerchip Semiconductor Manufacturing Corporation, Hsinchu (TW)

(72) Inventors: Ju-Chun Tien, Hsinchu (TW); Meng-Han Lin, Hsinchu City (TW); Yu Huan Sa, Hsinchu (TW); Yu-Chang Lin, Hsinchu (TW); Ying Chia Lin, Hsinchu City (TW)

(73) Assignee: Powerchip Semiconductor Manufacturing Corporation, Hsinchu (TW)

(21) Appl. No.: 19/077,037

(22) Filed: Mar. 11, 2025

(30) Foreign Application Priority Data
Feb. 25, 2025 (TW) 114106855

(51) Int. Cl. H10D 30/60; H01L 21/265; H01L 21/762; H10D 30/01; H10D 64/01; H10D 64/60

(52) U.S. Cl. CPC H10D 30/601; H10D 30/0227; H10D 64/01; H10D 64/605; H10P 30/204; H10P 30/21; H10W 10/014; H10W 10/17

(57) ABSTRACT

A method of manufacturing a semiconductor device is provided. The manufacturing method includes the following steps. An element isolation structure is formed in a substrate to define an active region. The active region includes multiple edge regions and a central region located between the edge regions. Then, a well region is formed in the active region. Multiple lightly-doped drain (LDD) regions are first formed in the well region. Then, a gate structure is formed on the substrate and across the active region. Due to the LDD regions, an average doping concentration in the edge region below the gate structure is lower than an average doping concentration in the central region below the gate structure. Multiple source/drain regions are formed in the LDD regions.

### CROSS-REFERENCE TO RELATED APPLICATION

This application claims the priority benefit of Taiwan application serial no. 114106855, filed on Feb. 25, 2025. The entirety of the above-mentioned patent application is hereby incorporated by reference herein and made a part of this specification.

### BACKGROUND

### Technical Field

The disclosure relates to a semiconductor process, and in particular to a semiconductor device and a method of manufacturing the same.

### Description of Related Art

Currently, metal-oxide-semiconductor (MOS) devices have developed a gate-last process, which uses a metal gate to replace a polysilicon gate to resolve electrical issues caused by gate size reduction.

However, an active region edge of a wide-edge device is prone to early triggering, causing a double hump phenomenon in the subthreshold region of the IV curve, which affects semiconductor device properties.

### SUMMARY

The disclosure provides a semiconductor device and a method of manufacturing the same. The semiconductor device may resolve the double hump issue and may be integrated into a CMOS process.

A method of manufacturing a semiconductor device of the disclosure includes the following steps. An element isolation structure is formed in a substrate to define an active region. The active region includes multiple edge regions and a central region located between the edge regions. A well region is formed in the active region. Multiple lightly-doped drain regions are first formed in the well region. Then, a gate structure is formed on the substrate and across the active region. Due to the lightly-doped drain regions, an average doping concentration in the edge region below the gate structure is lower than an average doping concentration in the central region below the gate structure. A source/drain region is formed in the lightly-doped drain regions.

In an embodiment of the disclosure, a method of forming the lightly-doped drain regions includes the following steps. A doped region having a first width is formed in the edge region. A doped region having a second width is formed in the central region. The first width is less than the second width.

In an embodiment of the disclosure, a method of forming the lightly-doped drain regions includes the following steps. Two rectangular doped regions are formed in the well region, and a counter-doping process is performed on the two rectangular doped regions in the edge region to reduce the average doping concentration in the edge region.

In an embodiment of the disclosure, a method of forming the lightly-doped drain regions includes the following steps. Two rectangular doped regions are formed in the well region, and another ion implantation process is performed on the two rectangular doped regions in the central region to increase the average doping concentration in the central region.

In an embodiment of the disclosure, a method of forming the gate structure includes the following steps. A gate oxide layer, a high dielectric constant material layer, a barrier layer, a dummy gate layer, and a hard mask layer are sequentially formed above a surface of the substrate. The hard mask layer is patterned. The patterned hard mask layer is used as an etching mask to etch the dummy gate layer, the barrier layer, the high dielectric constant material layer, and the gate oxide layer. A gate replacement process is used to replace the dummy gate layer with a metal gate.

In an embodiment of the disclosure, a method of forming the gate structure includes the following steps. A gate oxide layer, a gate layer, and a hard mask layer are sequentially formed above a surface of the substrate. The hard mask layer is patterned. The patterned hard mask layer is used as an etching mask to etch the gate layer and the gate oxide layer. The hard mask layer is removed.

In an embodiment of the disclosure, the lightly-doped drain regions are two asymmetric L-shaped doped regions.

A semiconductor device of the disclosure includes a substrate, an element isolation structure, a well region, a gate structure, multiple lightly-doped drain regions, and multiple source/drain regions. The element isolation structure is formed in the substrate to define an active region. The active region includes multiple edge regions and a central region located between the edge regions. The well region is formed in the active region. The gate structure is formed on a surface of the substrate and across the active region. The lightly-doped drain regions are formed in the well region, such that an average doping concentration in the edge region below the gate structure is lower than an average doping concentration in the central region below the gate structure. The source/drain regions are formed in the lightly-doped drain regions.

In another embodiment of the disclosure, the lightly-doped drain regions include a doped region having a first width in the edge region and a doped region having a second width in the central region. The first width is less than the second width.

In another embodiment of the disclosure, the gate structure includes a high dielectric constant metal gate structure or a poly-SiON structure.

In each embodiment of the disclosure, in a top view, an edge of the doped region having the first width may be aligned with a sidewall of the gate structure, the doped region having the first width may partially overlap the gate structure, or the doped region having the first width may not overlap the gate structure.

To make the features of the disclosure more comprehensible, several embodiments accompanied with drawings are described in detail as follows.

### BRIEF DESCRIPTION OF THE DRAWINGS

FIGS. 1A to 1H are cross-sectional views of a manufacturing process of a semiconductor device according to a first embodiment of the disclosure.

FIG. 2 is a top view of the structure in FIG. 1A.

FIG. 3 is a cross-sectional view taken along line X-X of FIG. 2.

FIG. 4 is a top view of the semiconductor device in FIG. 1H.

FIG. 5 is a cross-sectional view taken along line X-X of FIG. 4.

FIG. 6 is an IV curve diagram comparing a general semiconductor device and the semiconductor device of the first embodiment.

FIGS. 7A to 7E are top views of various examples of the semiconductor device in a second embodiment.

### DESCRIPTION OF THE EMBODIMENTS

The disclosure may be understood by referring to the following detailed description in conjunction with the drawings. Moreover, the sizes of various regions in the drawings are provided for illustration only and are not intended to limit the scope of the disclosure.

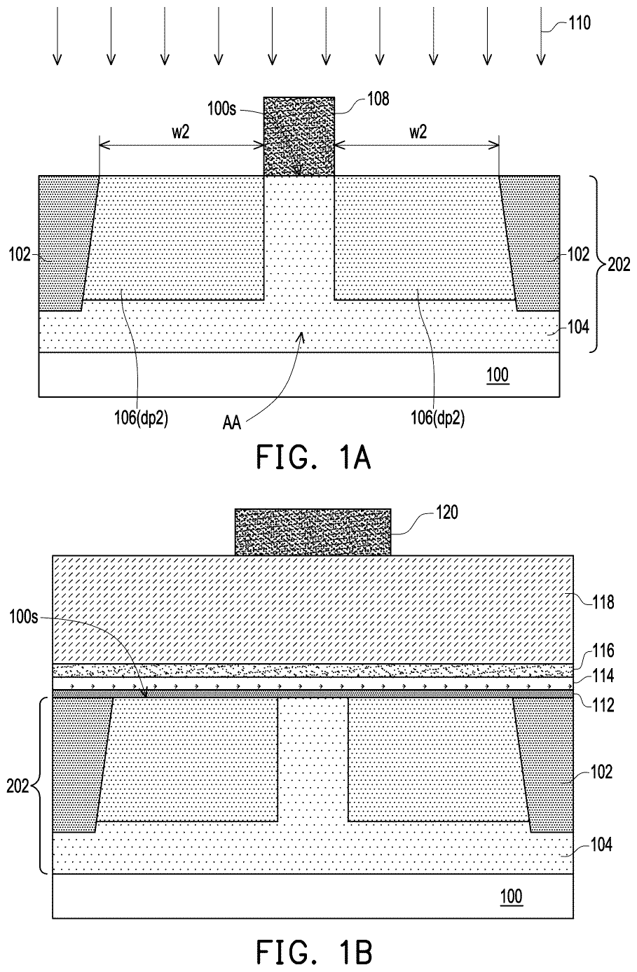

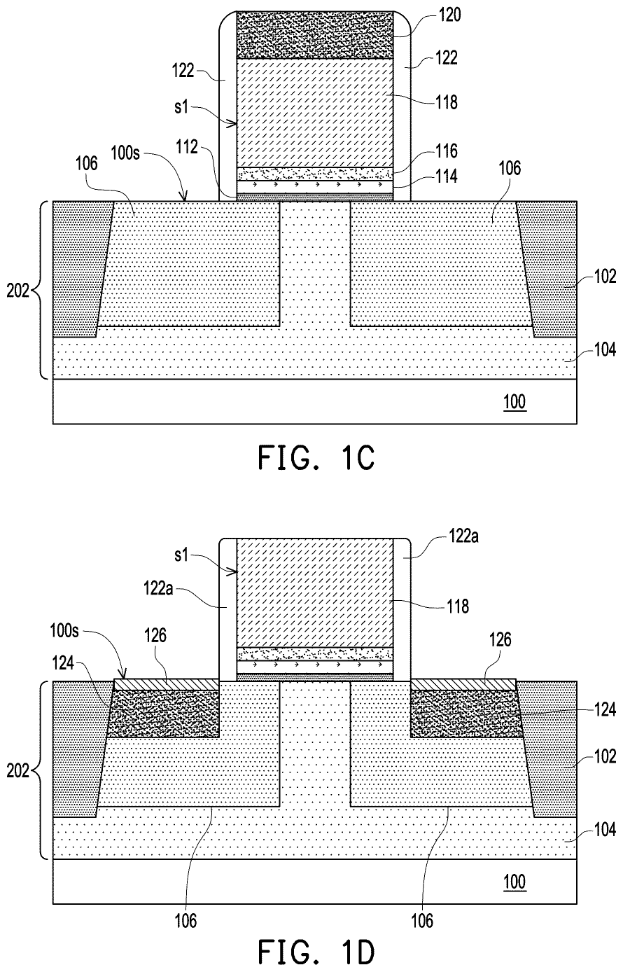

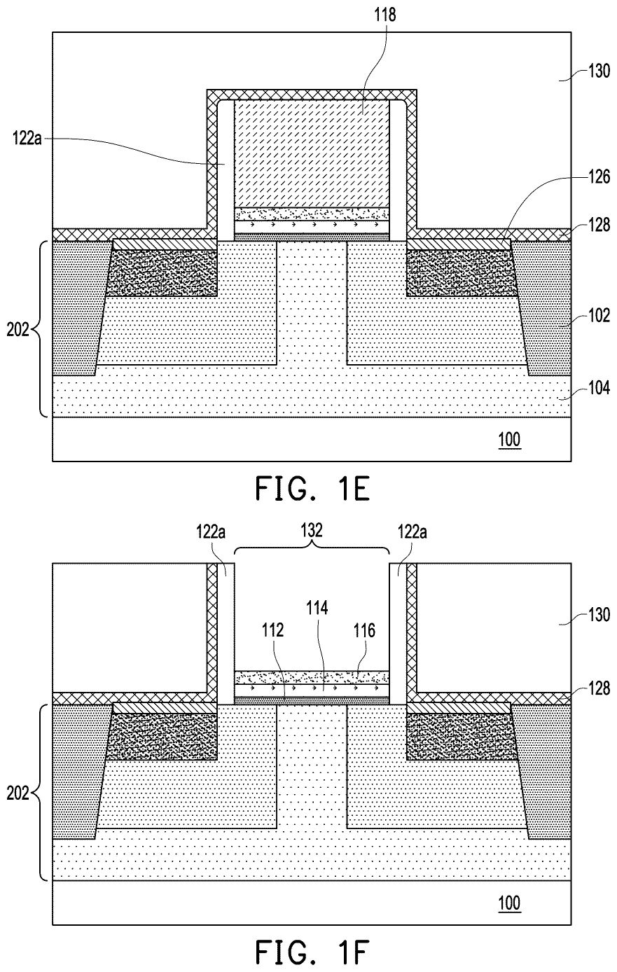

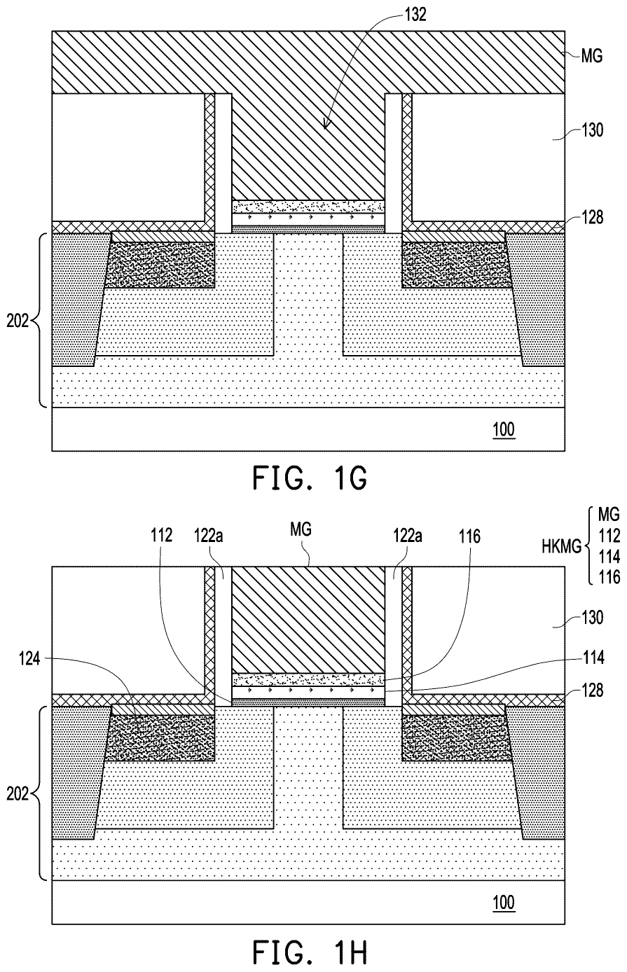

FIGS. 1A to 1H are cross-sectional views of a manufacturing process of a semiconductor device according to a first embodiment of the disclosure.

Referring to FIG. 1A, an element isolation structure 102 is formed in a substrate 100 to define an active region AA. Then, a well region 104 is first formed in the active region AA. Next, a plurality of lightly-doped drain (LDD) regions 106 are first formed in the well region 104. A method of forming the LDD regions 106 includes, for example, first forming a patterned mask 108 on a surface 100s of the substrate 100 and then performing an ion implantation process 110.

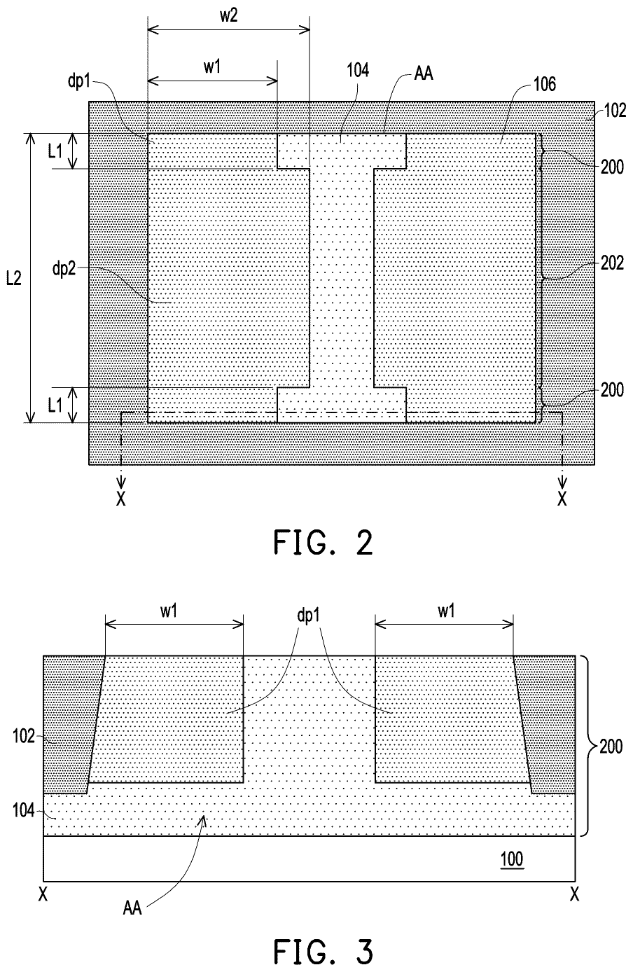

FIG. 2 is a top view of the structure in FIG. 1A, where the active region AA includes an edge region 200 and a central region 202 located between the edge region 200. In an embodiment, a sum of a length L1 of an upper edge region 200 and a length L1 of a lower edge region 200 accounts for about 5% to 40% of a length L2 of the entire active region AA, for example, 5% to 30% or 5% to 20%.

Referring to both FIG. 1A and FIG. 2, a method of forming the LDD regions 106 includes, for example, forming a doped region dp1 having a first width w1 in the edge region 200 and forming a doped region dp2 having a second width w2 in the central region 202. The first width w1 is less than the second width w2.

FIG. 3 is a cross-sectional view taken along line X-X of FIG. 2. FIG. 3 shows that the doped region dp1 having the first width w1 in the edge region 200 is a part of the LDD regions 106 in FIG. 2. Compared with the doped region dp2 having the second width w2 in FIG. 1A, since the area occupied by the doped region dp1 is smaller, an average doping concentration in the edge region 200 is lower than an average doping concentration in the central region 202. The term “average doping concentration” refers to an average value of doping concentrations of all doped regions in a cross-section. Taking the central region 202 in FIG. 2 as an example, the corresponding cross-section is FIG. 1A. In FIG. 1A, an area of the doped region dp2 is obviously larger than an area of the doped region dp1 in FIG. 3. Therefore, the average doping concentration in the central region 202 is greater than the average doping concentration in the edge region 200.

Referring to FIG. 1B, after removing the patterned mask 108 in FIG. 1A, a gate oxide layer 112, a high dielectric constant material layer 114, a barrier layer 116, a dummy gate layer 118, and a hard mask layer 120 are sequentially formed above a surface 100s of the substrate 100. The high dielectric constant material layer 114 may include a dielectric material having a high dielectric constant. For example, the dielectric material having a high dielectric constant may be a material with a dielectric constant greater than that of silicon oxide (approximately 3.9). In some embodiments, the high dielectric constant material layer 114 includes, for example, HfO₂, TiO₂, HfZrO, Ta₂O₂, HfSiO₄, ZrO₂, ZrSiO₂, LaO, AlO, ZrO, TiO, Ta₂O₅, Y₂O₃, BaZrO, HfZrO, HfLaO, HfSiO, LaSiO, AlSiO, HfTaO, HfTiO, Al₂O₃, Si₃N₄, SiON, or a combination thereof. The barrier layer 116 may include TiN or other suitable materials. The dummy gate layer 118 may include polysilicon. The hard mask layer 120 may include an oxide, a nitride, or a combination thereof. Then, using photolithography and etching processes, the hard mask layer 120 is patterned to expose a portion of the dummy gate layer 118.

Referring to FIG. 1C, the patterned hard mask layer 120 is used as an etching mask to etch the dummy gate layer 118, the barrier layer 116, the high dielectric constant material layer 114, and the gate oxide layer 112 until the surface 100s of the substrate 100 is exposed. Subsequently, a gate replacement process may be used to replace the dummy gate layer 118 with a metal gate. For example, a spacer 122 may first be formed on a sidewall s1. The spacer 122 may include silicon oxide, silicon nitride, or a combination thereof.

Referring to FIG. 1D, an ion implantation process is used to form a source/drain region 124 in the LDD region 106. Then, a metal silicide layer 126 may be formed on the exposed surface 100s of the substrate 100. Afterward, the hard mask layer 120 in FIG. 1C is removed, along with a portion of the spacer 122, resulting in spacers 122a located on both sides of the dummy gate layer 118.

Referring to FIG. 1E, an etch stop layer 128 is first deposited to cover the metal silicide layer 126, the spacers 122a, and the surface of the dummy gate layer 118. Then, an ILD layer 130 is formed to cover the etch stop layer 128 and the entire dummy gate layer 118.

Referring to FIG. 1F, the ILD layer 130 and the etch stop layer 128 undergo a planarization process, such as CMP, until the dummy gate layer 118 under the etch stop layer 128 (from FIG. 1E) is exposed. The dummy gate layer 118 is then removed, forming an opening 132. The opening 132 is a space defined by the spacers 122a and the barrier layer 116.

Referring to FIG. 1G, a metal gate layer MG is formed above the substrate 100, and the metal gate layer MG fills the opening 132. The metal gate layer MG may include tantalum nitride (TaN), nickel silicide (NiSi), cobalt silicide (CoSi), molybdenum (Mo), copper (Cu), tungsten (W), aluminum (Al), cobalt (Co), zirconium (Zr), platinum (Pt), or other suitable materials.

Referring to FIG. 1H, the metal gate layer MG undergoes a planarization process, such as CMP, to form a gate structure HKMG. The gate structure HKMG may include the gate oxide layer 112, the high dielectric constant material layer 114, the barrier layer 116, and the metal gate layer MG.

Besides the gate structure HKMG formed by the gate replacement process, the disclosure may also be applied to a process where the gate structure is a poly-SiON structure. For example, in the step shown in FIG. 1B, after forming the gate oxide layer 112, a polysilicon layer (not shown) is directly formed instead of forming the barrier layer 116 and the high dielectric constant material layer 114. Then, by performing the etching step shown in FIG. 1C, the poly-SiON structure is formed. Subsequently, as in the step shown in FIG. 1D, the source/drain regions 124 are formed in the LDD regions 106 to complete an embodiment of the semiconductor device of the disclosure.

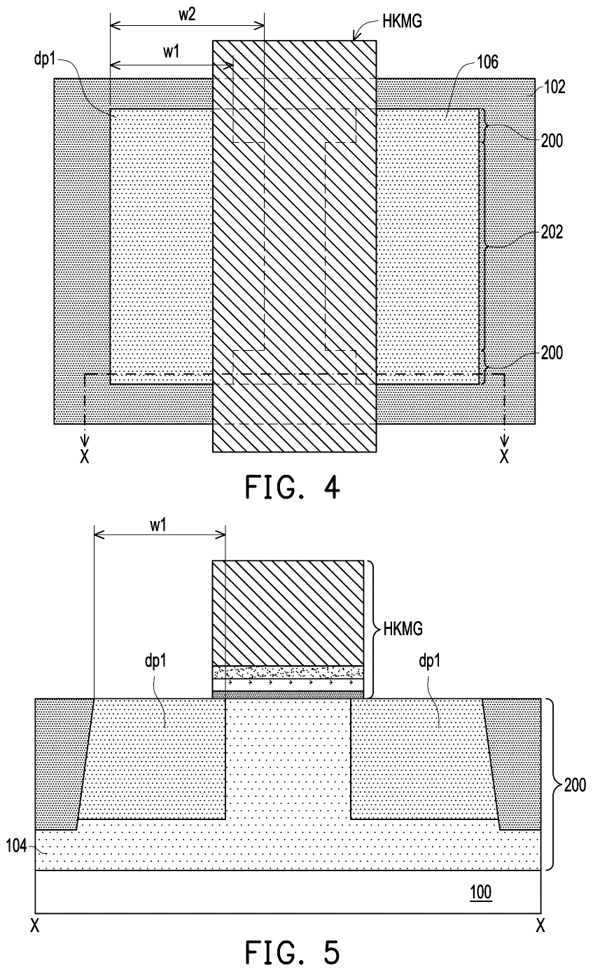

FIG. 4 is a top view of the structure shown in FIG. 1H. For clarity, some components are omitted, including the ILD layer 130, the etch stop layer 128, the spacers 122a, the source/drain region 124, and the metal silicide layer 126 from FIG. 1H. FIG. 5 is a cross-sectional view taken along line X-X of FIG. 4.

Referring to FIGS. 4 and 5, the doped region dp1 having the first width w1 partially overlaps the gate structure HKMG. The average doping concentration in the edge region 200 below the gate structure HKMG is lower than the average doping concentration in the central region 202 below the gate structure HKMG.

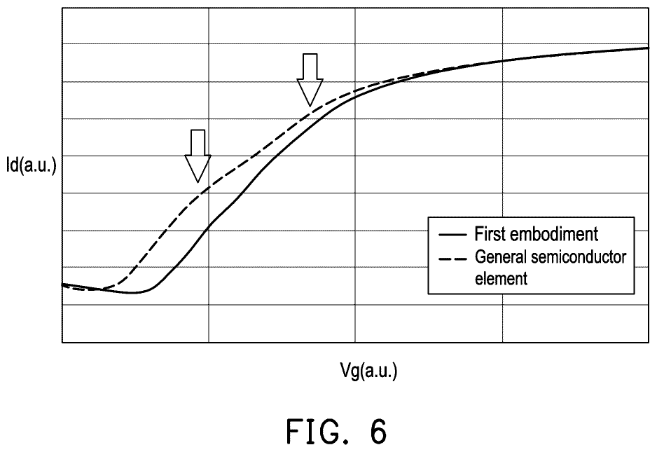

FIG. 6 is an IV curve diagram comparing a general semiconductor device and the semiconductor device of the first embodiment. Referring to FIG. 6, the IV curve of a general semiconductor device exhibits a double hump phenomenon. However, in the semiconductor device of the first embodiment, because the average doping concentration in the edge portion of the active region is low, the threshold voltage (Vth) in this region is increased. As a result, an IV curve without a double hump is obtained, thereby preventing the edge region from being turned on in advance.

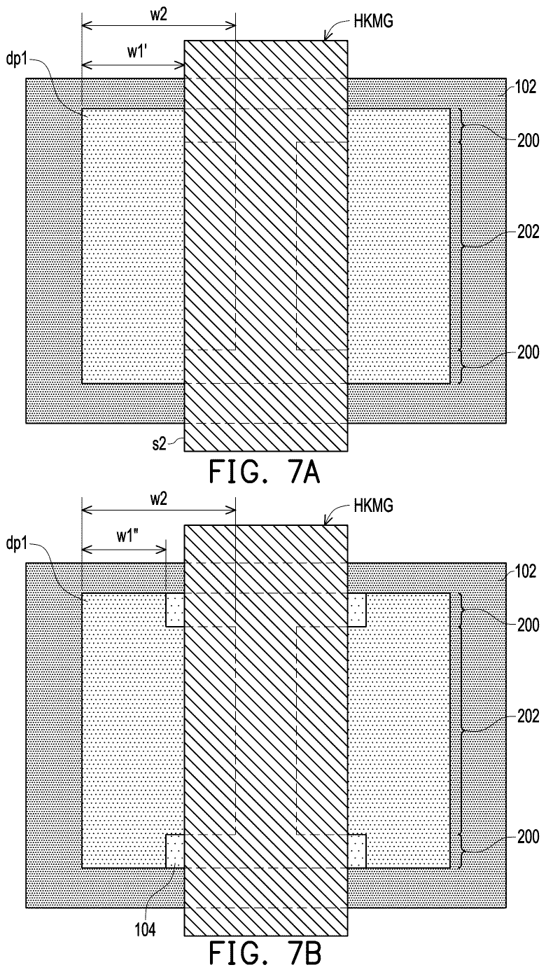

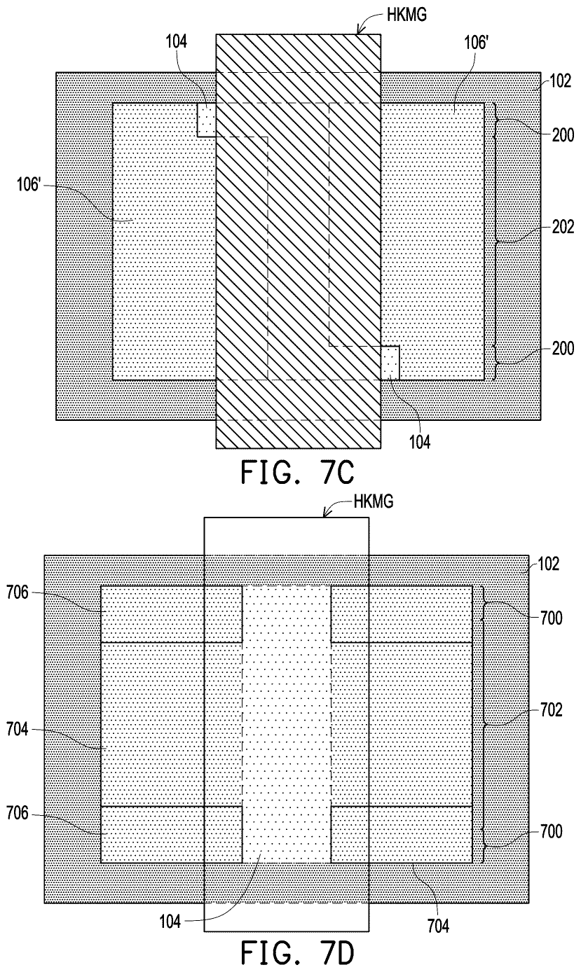

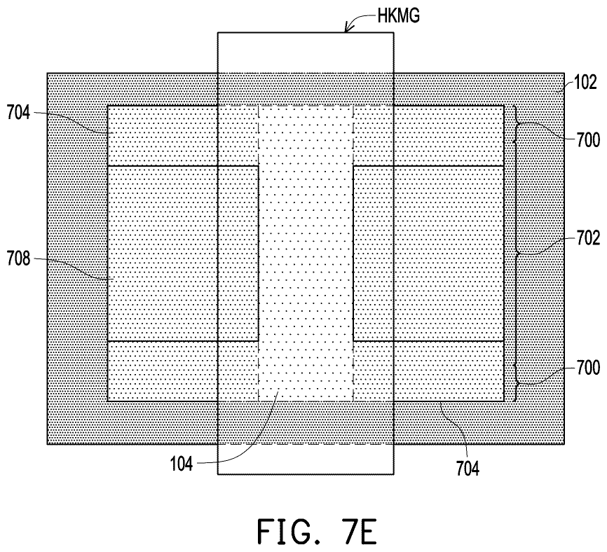

To ensure that the average doping concentration in the edge region of the active region below the gate structure is lower than the average doping concentration in the central region of the active region below the gate structure, various technical methods may be used, as illustrated by the multiple examples shown in FIGS. 7A to 7E.

In FIG. 7A, an edge of the doped region dp1 having a first width w1′ is aligned with a sidewall s2 of the gate structure HKMG.

In FIG. 7B, the doped region dp1 having a first width w1″ does not overlap the gate structure HKMG.

In FIG. 7C, LDD regions 106′ are two asymmetric L-shaped doped regions. That is, the left LDD region 106′ and the right LDD region 106′ are not mirror-symmetrical. In some embodiments, the area of the left LDD region 106′ is equal to the area of the right LDD region 106′.

Additionally, process control may also ensure that the average doping concentration in an edge region 700 below the gate structure HKMG is lower than the average doping concentration in a central region 702 below the gate structure HKMG.

For example, in FIG. 7D, two rectangular doped regions 704 are first formed in the well region 104 through an ion implantation process. The range of the rectangular doped regions 704 covers the upper edge region 700, the lower edge region 700, and the central region 702. Then, a counter-doping process is performed on the two rectangular doped regions 704 in the edge region 700 to form counter-doped regions 706, thereby reducing the average doping concentration in the edge region 700.

In FIG. 7E, two rectangular doped regions 704 are first formed in the well region 104 through an ion implantation process. Then, another ion implantation process is performed on the two rectangular doped regions 704 in the central region 702 to form doped regions 708, thereby increasing the average doping concentration in the central region 702.

Based on the above, the disclosure adopts a method where the LDD regions are formed first, followed by the formation of the gate. Therefore, LDD regions of specific shapes may be fabricated according to requirements, and the double hump phenomenon in semiconductor devices may be eliminated.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A method of manufacturing a semiconductor device, comprising:
forming an element isolation structure in a substrate to define an active region, wherein the active region comprises a plurality of edge regions and a central region located between the plurality of edge regions;
forming a well region in the active region;
forming a plurality of lightly-doped drain regions in the well region;
forming a gate structure on the substrate and across the active region, wherein due to the plurality of lightly-doped drain regions, an average doping concentration in the edge region below the gate structure is lower than an average doping concentration in the central region below the gate structure; and
forming a source/drain region in the plurality of lightly-doped drain regions.

2. The method of manufacturing the semiconductor device according to claim 1, wherein a method of forming the plurality of lightly-doped drain regions comprises forming a doped region having a first width in the edge region and forming a doped region having a second width in the central region, and the first width is less than the second width.

3. The method of manufacturing the semiconductor device according to claim 2, wherein, in a top view, an edge of the doped region having the first width is aligned with a sidewall of the gate structure.

4. The method of manufacturing the semiconductor device according to claim 2, wherein, in a top view, the doped region having the first width partially overlaps the gate structure.

5. The method of manufacturing the semiconductor device according to claim 2, wherein, in a top view, the doped region having the first width does not overlap the gate structure.

6. The method of manufacturing the semiconductor device according to claim 1, wherein, in a top view, the plurality of lightly-doped drain regions are two asymmetric L-shaped doped regions.

7. The method of manufacturing the semiconductor device according to claim 1, wherein a method of forming the plurality of lightly-doped drain regions comprises:
forming two rectangular doped regions in the well region; and
performing a counter-doping process on the two rectangular doped regions in the edge region to reduce the average doping concentration in the edge region.

8. The method of manufacturing the semiconductor device according to claim 1, wherein a method of forming the plurality of lightly-doped drain regions comprises:
forming two rectangular doped regions in the well region; and
performing another ion implantation process on the two rectangular doped regions in the central region to increase the average doping concentration in the central region.

9. The method of manufacturing the semiconductor device according to claim 1, wherein forming the gate structure comprises:
sequentially forming a gate oxide layer, a high dielectric constant material layer, a barrier layer, a polysilicon layer, a dummy gate layer, and a hard mask layer above a surface of the substrate;
patterning the hard mask layer;
using the patterned hard mask layer as an etching mask to etch the dummy gate layer, the barrier layer, the high dielectric constant material layer, and the gate oxide layer; and
replacing the dummy gate layer with a metal gate by using a gate replacement process.

10. The method of manufacturing the semiconductor device according to claim 1, wherein forming the gate structure comprises:
sequentially forming a gate oxide layer, a gate layer, and a hard mask layer above a surface of the substrate;
patterning the hard mask layer;
using the patterned hard mask layer as an etching mask to etch the gate layer and the gate oxide layer; and
removing the hard mask layer.

11. A semiconductor device, comprising:
a substrate;
an element isolation structure, formed in the substrate to define an active region, wherein the active region comprises a plurality of edge regions and a central region located between the plurality of edge regions;
a well region, formed in the active region;
a gate structure, formed on a surface of the substrate and across the active region;
a plurality of lightly-doped drain regions, formed in the well region, such that an average doping concentration in the edge region below the gate structure is lower than an average doping concentration in the central region below the gate structure; and
a source/drain region, formed in the plurality of lightly-doped drain regions.

12. The semiconductor device according to claim 11, wherein the plurality of lightly-doped drain regions comprises a doped region having a first width in the edge region and a doped region having a second width in the central region, and the first width is less than the second width.

13. The semiconductor device according to claim 12, wherein, in a top view, an edge of the doped region having the first width is aligned with a sidewall of the gate structure.

14. The semiconductor device according to claim 12, wherein, in a top view, the doped region having the first width partially overlaps the gate structure.

15. The semiconductor device according to claim 12, wherein, in a top view, the doped region having the first width does not overlap the gate structure.

16. The semiconductor device according to claim 11, wherein the plurality of lightly-doped drain regions are two asymmetric L-shaped doped regions.

17. The semiconductor device according to claim 11, wherein the gate structure comprises a high dielectric constant metal gate structure or a poly-SiON structure.
